(19) United States
(12) Patent Application Publication
(10) Pub. No.: US 2026/0080922 A1
(43) Pub. Date: Mar. 19, 2026

(54) RACETRACK WIRE, MAGNETIC MEMORY DEVICE USING THE RACETRACK WIRE, AND OPERATION METHOD OF THE MAGNETIC MEMORY DEVICE

(71) Applicant: Samsung Electronics Co., Ltd., Suwon-si (KR)

(72) Inventors: Soichiro MIZUSAKI, Suwon-si (KR); Kwangseok KIM, Suwon-si (KR); Unghwan PI, Suwon-si (KR); Jungsik PARK, Suwon-si (KR)

(73) Assignee: Samsung Electronics Co., Ltd., Suwon-si (KR)

(21) Appl. No.: 19/020,358

(22) Filed: Jan. 14, 2025

(30) Foreign Application Priority Data
Sep. 13, 2024 (KR) 10-2024-0126190

(51) Int. Cl. G11C 11/16; G11C 19/08; H01F 10/32; H10N 50/10; H10N 50/85

(52) U.S. Cl. CPC G11C 11/161; G11C 11/1673; G11C 11/1675; G11C 19/0841; H01F 10/3272; H10N 50/10; H10N 50/85

(57) ABSTRACT

Provided is a magnetic memory device including a moving element, a write element configured to inject a magnetic domain into the moving element, and a read element apart from the write element in a length direction of the moving element and configured to read the magnetic domain of the moving element. The moving element includes a free layer. A pinning site providing layer faces the free layer. The pinning site providing layer includes a plurality of first regions including an antiferromagnetic material. The plurality of first regions are apart from each other in the length direction of the moving element and lower the magnetic anisotropy energy of regions of the free layer facing the plurality of first regions. A plurality of pinning sites configured to pin the magnetic domains to regions of the free layer facing the plurality of first region may be provided by the plurality of first regions.

### CROSS-REFERENCE TO RELATED APPLICATIONS

This application is based on and claims priority under 35 U.S.C. § 119 to Korean Patent Application Nos. 10-2024-0126190, filed on Sep. 13, 2024 in the Korean Intellectual Property Office, the disclosure of which is incorporated by reference herein in its entirety.

### BACKGROUND

Some example embodiments relate to a racetrack wire, a magnetic memory device using the racetrack wire, and/or an operation method of the magnetic memory device.

Racetrack memory devices use magnetic domains as memory units and may store information as “1” or “0” according to directions of the magnetic domains. Racetrack memory devices may have characteristics in which the movement directions of the magnetic domains in a racetrack change according to a direction in which a current flows. Racetrack memory devices have gained attention due to having a high capacity, since the movement speed of the magnetic domains is very high and the size of the magnetic domains is very small.

In racetrack memory devices, the location stability of the magnetic domain is important. When the magnetic domain is moved along the racetrack, the magnetic domain needs to or should be pinned at a desired position. To this end, various shapes of pinning sites have been provided in the racetrack.

### SUMMARY

Provided is a magnetic memory device having improved positional stability of a magnetic domain. Alternatively or additionally, provided is a magnetic memory device with improved data retention performance.

Alternatively or additionally, provided is a magnetic memory device with variable pinning sites.

Additional aspects will be set forth in part in the description which follows and, in part, will be apparent from the description, and/or may be learned by practice of some example embodiments.

According to some example embodiments, a magnetic memory device includes a moving element including a free layer, a write element configured to generate a magnetic domain on the free layer, a moving electrode configured to supply a current to move the magnetic domain to the moving element, a read element apart from the write element in a length direction of the moving element and configured to read the magnetic domain of the free layer, and a pinning site providing layer facing the free layer. The pinning site providing layer includes a plurality of first regions that include an antiferromagnetic material, are apart from each other in the length direction of the moving element, and are configured to reduce a magnetic anisotropy energy of regions of the free layer facing the plurality of first regions.

Alternatively or additionally according to some example embodiments, a racetrack wire includes a free layer configured to generate a magnetic domain, a pinning site providing layer including a plurality of first regions including an antiferromagnetic material, apart from each other in a length direction of the free layer, and configured to reduce a magnetic anisotropy energy of regions of the free layer facing the plurality of first regions, and a dielectric layer on the free layer.

Alternatively or additionally according to some example embodiments, an operation method of driving a magnetic memory device includes providing a magnetic memory device, the magnetic memory device including a free layer, a pinning site providing layer, and a temperature controller, wherein the pinning site providing layer includes a plurality of first regions that include an antiferromagnetic material, are apart from each other in a length direction of the moving element, and are configured to reduce a magnetic anisotropy energy of regions of the free layer facing the plurality of first regions, and the temperature controller is configured to control a temperature of the plurality of first regions. The method further includes driving the temperature controller to control the temperature of the plurality of first regions to be less than a blocking temperature of the antiferromagnetic material.

### BRIEF DESCRIPTION OF THE DRAWINGS

The above and other aspects, features, and advantages of some example embodiments will be more apparent from the following description taken in conjunction with the accompanying drawings, in which:

FIG. 1 is a schematic cross-sectional view of a racetrack wire according to some example embodiments;

FIG. 2 shows a function of a pinning site providing layer in the racetrack wire of FIG. 1;

FIGS. 3A, 3B, and 3C show examples of the relationship between a thickness of an antiferromagnetic material and an intensity of an exchange bias field;

FIGS. 4A, 4B, and 4C show examples of a relationship between a temperature and the intensity of the exchange bias field;

FIG. 5 is a schematic cross-sectional view of a racetrack wire according to some example embodiments;

FIG. 6 is a drawing showing a function of a pinning site providing layer in the racetrack wire of FIG. 5;

FIG. 7 is a schematic cross-sectional view of a racetrack wire according to some example embodiments;

FIG. 8 is a schematic cross-sectional view of a racetrack wire according to some example embodiments;

FIGS. 9A to 9F show an example of a method of manufacturing a racetrack wire.

FIG. 10 is a schematic cross-sectional view of a racetrack wire according to some example embodiments.

FIG. 11 is a schematic cross-sectional view of a racetrack wire according to some example embodiments;

FIG. 12 is a graph showing an example of a relationship between a thickness and a blocking temperature of an antiferromagnetic material;

FIG. 13 is a schematic cross-sectional view of a magnetic memory device according to some example embodiments;

FIGS. 14A to 14D illustrate a process of writing, moving, and reading a magnetic domain;

FIG. 15 is a schematic cross-sectional view of a magnetic memory device according to some example embodiments;

FIG. 16 is a circuit diagram schematically showing a structure of a memory apparatus including a plurality of memory cells; and

FIG. 17 is a conceptual diagram schematically showing a device architecture applicable to an electronic apparatus according to embodiments.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

A pinning site to fix a magnetic domain to a free layer is required or used in a magnetic memory device (magnetoresistive memory device). To this end, there are methods such as doping a portion of the free layer with impurities to lower the magnetic anisotropy energy of the doped region, and forming a notch in the free layer. It may be difficult to apply the method of doping impurities onto a portion of the free layer to a synthetic antiferromagnetic structure, and the method of forming a notch may cause a change in the physical properties of the free layer due to the heat generated during the operation of the magnetic memory device.

Some example embodiments provide a pinning site capable of stably fixing the position of a magnetic domain. Some example embodiments provide a structure wherein the position of the pinning site may be changed without changing the physical structure of a free layer, e.g., without forming a notch therein. To this end, a plurality of regions including antiferromagnetic materials are provided at a position facing the free layer, and the magnetic anisotropy energy of the regions of the free layer facing the plurality of regions are lowered by using an exchange bias field or a stray field provided by the antiferromagnetic material, thereby providing the pinning site in the free layer. Additionally or alternatively, by controlling the temperature of the plurality of regions including the antiferromagnetic materials by using a temperature controller, the number and position of the pinning site may change without changing the physical structure of the magnetic memory device.

Hereinafter, with reference to the attached drawings, a magnetic memory device according to various example embodiments will be described in detail. In the drawings, like reference numerals demote like elements, and sizes of each component are exaggerated for clarity and convenience in explanation. In addition, the following embodiments described are provided only as an example and thus may be embodied in various forms.

It will be understood that when a component is referred to as being “on” or “on the top of” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. It will be further understood that when a portion is referred to as “comprises” another component, the portion may not exclude another component but may further comprise another component unless the context states otherwise.

As used herein, terms such as “the” and similar demonstratives may indicate both the singular and plural forms. Also, the steps of all methods described herein can be performed in any suitable order unless otherwise indicated herein or otherwise clearly contradicted by context. Embodiments are not limited to the described order of the steps.

The connection or connection members of the lines between the elements shown in the drawing are examples of functional connection and/or physical or circuit connections, and may be replaced or be implemented as various functional connections, physical connections, or circuit connections in an actual apparatus.

The use of any and all examples, or exemplary language provided herein, is intended merely to better illuminate example embodiments and does not pose a limitation on the scope of embodiments unless otherwise claimed.

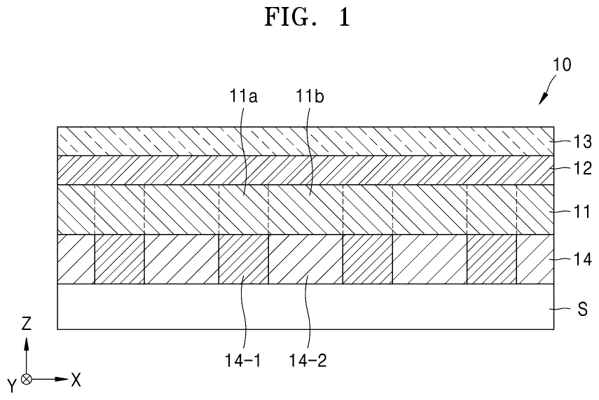

FIG. 1 is a schematic cross-sectional view of a racetrack wire 10 according to some example embodiments. The racetrack wire 10 may be a moving element of a magnetic memory device described below, for example, a racetrack memory device. The moving element of the racetrack memory device may be referred to as a racetrack. In the drawings below, X represents a length direction of each layer, Y represents a width direction of each layer, and Z represents a thickness direction of each layer. Each of X, Y, and Z may be orthogonal to each other; example embodiments are not limited thereto.

Referring to FIG. 1, the racetrack wire 10 has a length in the X direction and a width in the Y direction. The length of the racetrack wire 10 may be greater than the width thereof. The racetrack wire 10 may include a free layer 11 and a pinning site providing layer 14. A magnetic domain is generated in the free layer 11, and when a current such as a direct current (DC) is supplied to the free layer 11, the magnetic domain moves in the length direction, for example, in the +X direction or −X direction. A direction of movement of the magnetic domain may be according to a direction of the current. The pinning site providing layer 14 may face the free layer 11 and may provide a plurality of pinning sites for fixing the magnetic domains generated in the free layer 11. The plurality of pinning sites be apart from each other in the length direction of the free layer 11, that is, in the X direction.

The free layer 11 may have a single-layer structure including a ferromagnetic material. For example, the free layer 11 may be or may include a ferromagnetic layer including a ferromagnetic metal material having magnetism. The free layer 11 may include at least one ferromagnetic material selected from a group consisting of or the group including iron (Fe), cobalt (Co), nickel (Ni), manganese (Mn), Fe-containing alloys, Co-containing alloys, Ni-containing alloys, Mn-containing alloys, and Heusler alloys. In some example embodiments, the free layer 11 may include CoFeB. The free layer 11 may have high magnetic anisotropy, for example, high perpendicular magnetic anisotropy (PMA). The PMA energy of the free layer 11 may exceed an out-of-plane demagnetization energy. In this case, the magnetic moment of the free layer 11 may be stabilized in the thickness direction (Z) perpendicular to a plane, for example, an X-Y plane. For example, for the magnetization direction of the free layer 11 to be easily changed even with a low current, the free layer 11 may be doped with at least one non-magnetic metal selected from a group consisting of or the group including Mg, Ru, Ir, Ti, Zn, Ga, Ta, Al, Mo, Zr, Sn, W, Sb, V, Nb, Cr, Ge, Si, Hf, Tb, Sc, Y, Rh, In, Ca, Sr, Ba, Be, V, Li, Cd, Pb, Ga, and Mo.

The pinning site providing layer 14 may face one surface of the free layer 11. The pinning site providing layer 14 may include a plurality of first regions 14-1. The plurality of first regions 14-1 may be apart from each other in the length direction (X) of the free layer 11. The length, e.g., the length in the X direction, of each of the plurality of first regions 14-1 is not particularly limited, and may be about 1 nm to about 1 μm as a non-limiting example. The first region 14-1 may include an antiferromagnetic material. For example, the antiferromagnetic material may include at least one of an oxide including Ni, Co, Mn, Fe, Cr, or Ru, IrMn, or PtMn. The antiferromagnetic material may include 3d-electrons and/or 4f-electrons.

The pinning site providing layer 14 may include the plurality of first regions 14-1 and a plurality of second regions 14-2 arranged alternately. The length, e.g., the length in the X-direction, of the second region 14-2 may be the same as or different from the length of the first region 14-1. The plurality of second regions 14-2 may include a material that does not affect the magnetic anisotropy energy of a region (a fourth region) 11b of the free layer 11 facing plurality of second regions 14-2. To this end, the plurality of second regions 14-2 may include a non-antiferromagnetic material. The non-antiferromagnetic material may include a paramagnetic material. The non-antiferromagnetic material may include a diamagnetic material. The non-antiferromagnetic material may include at least one of a paramagnetic material and a diamagnetic material. For example, the non-antiferromagnetic material may include at least one of SiO₂, AlOₓ, or nitride. The non-antiferromagnetic material may include a material having a paramagnetism at an operating temperature of the magnetic memory device. When the magnetic memory device operates, a current such as a direct current is applied to the racetrack wire 10, for example, to the free layer 11, so as to move the magnetic domain. In this case, since Joule heat is generated, when the magnetic memory device is continuously operated, the temperature of the magnetic memory device becomes greater than room temperature. Therefore, the operating temperature of the magnetic memory device may be greater than room temperature. For example, the non-antiferromagnetic material may include an antiferromagnetic material that is paramagnetic at the operating temperature of the magnetic memory device, for example, an antiferromagnetic material having a Neel temperature lower than the operating temperature of the magnetic memory device. For example, manganese-oxide (MnO), which is an antiferromagnetic material of which the Neel temperature is 116 K, is paramagnetic at an operating temperature of the magnetic memory device, and thus may be used as a non-antiferromagnetic material in the second region 14-2. Therefore, for example, a CoNiO/MnO combination may be applied to the first region 14-1 and/or to the second region 14-2.

The racetrack wire 10 may further include a dielectric layer 12. The dielectric layer 12 may cover a surface of the free layer 11. In some example embodiments, the dielectric layer 12 may cover the surface of the free layer 11 which is opposite to the surface of the free layer 11 that faces the pinning site providing layer 14. The dielectric layer 12 may include a metal oxide. The dielectric layer 12 may include magnesium oxide. For example, the dielectric layer 12 may include one or more of MgO, MgAl₂O₄, or MgTiOₓ. The dielectric layer 12 may have a single-layer structure or a multi-layer structure. A capping layer 13 may be further provided as a protective layer on the dielectric layer 12.

The pinning site providing layer 14, the free layer 11, the dielectric layer 12, and the capping layer 13 described above may be sequentially laminated on and/or deposited on the substrate S, and/or on a seed layer (not shown) on the substrate S.

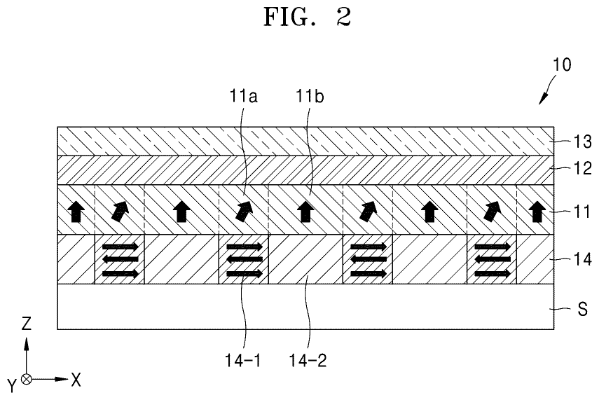

FIG. 2 is a drawing showing a function of the pinning site providing layer 14 in the racetrack wire 10 shown in FIG. 1. Referring to FIG. 2, the free layer 11 has PMA. The first region 14-1 of the pinning site providing layer 14 includes an antiferromagnetic material. The magnetic field of the antiferromagnetic material is applied to the first region 14-1 of the pinning site providing layer 14 and to the free layer 11 facing the first region 14-1, for example, the third region 11a of the ferromagnetic layer. Accordingly, a shift may occur in the magnetization curve of the third region 11a, and the degree of shift may be referred to as the exchange bias field. The exchange bias field may affect the magnetic anisotropy energy of the free layer 11. The magnetic anisotropy energy of the third region 11a is lowered by the exchange bias field provided by the antiferromagnetic material of the first region 14-1, which is indicated by a thick arrow tilted with respect to the +Z direction in FIG. 2. Since the second region 14-2 of the pinning site providing layer 14 includes a non-antiferromagnetic material, the second region 14-2 may not affect the magnetic anisotropy energy of the fourth region 11b of the free layer 11 facing the second region 14-2. This is indicated by a thick arrow in the +Z direction in FIG. 2. In this manner, the magnetic anisotropy energy of the third region 11a of the free layer 11 becomes lower than the magnetic anisotropy energy of the fourth region 11b of the free layer 11 due to the exchange bias field provided by the first region 14-1 including the antiferromagnetic material. When the magnetic domain moves, for example, in the −X direction, the movement speed of the domain wall is affected by the magnetic anisotropy energy, and the lower the magnetic anisotropy energy, the lower the speed of the domain wall movement. Accordingly, the first region 14-1 of the pinning site providing layer 14 may form a pinning site in the third region 11a of the free layer 11 facing the first region 14-1, and the magnetic domain may be pinned to the third region 11a of the free layer 11.

In some example embodiments, a plurality of pinning sites may be provided in the free layer 11, without applying or having physical changes to the free layer 11, such as without notches and/or without any doping. In the process of manufacturing the racetrack wire 10 including the plurality of pinning sites, the properties of the free layer 11 as a ferromagnetic layer may not be affected. The Joule heat may not be generated during the operation of the racetrack wire 10. Therefore, the positional stability of the magnetic domain and/or data retention performance may be improved.

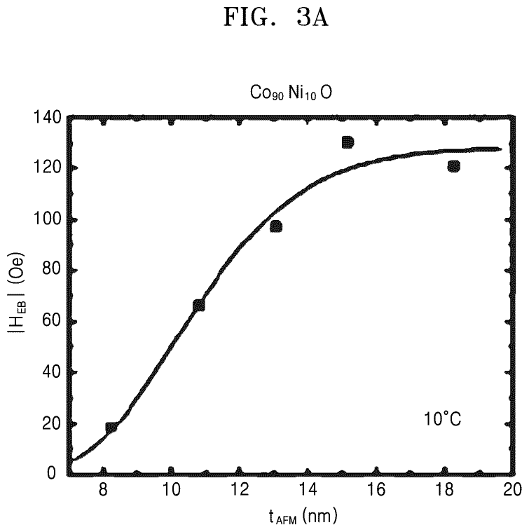

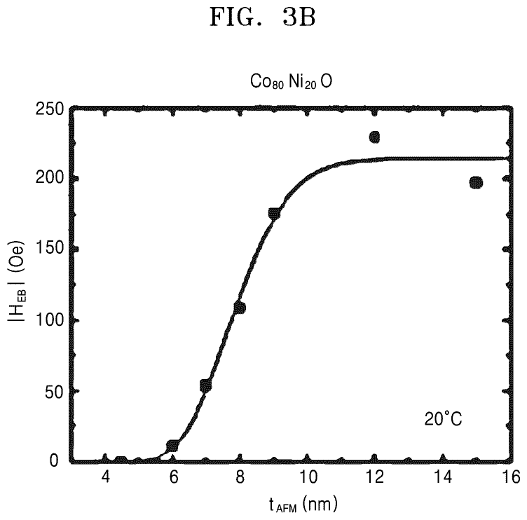

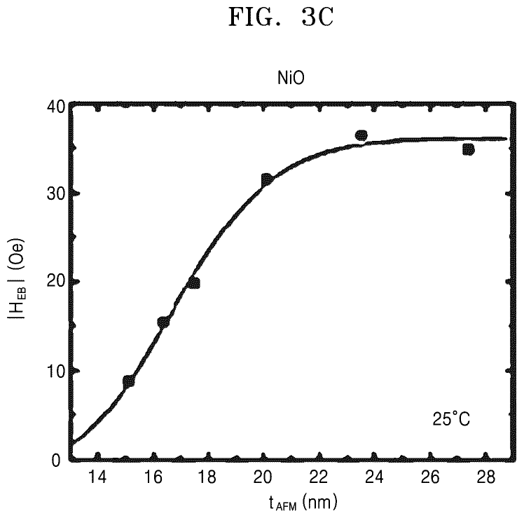

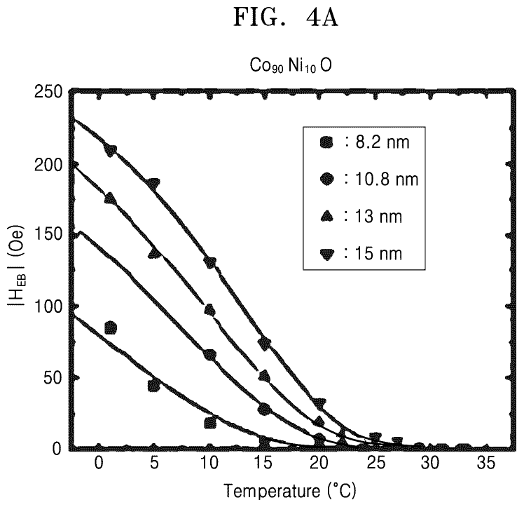

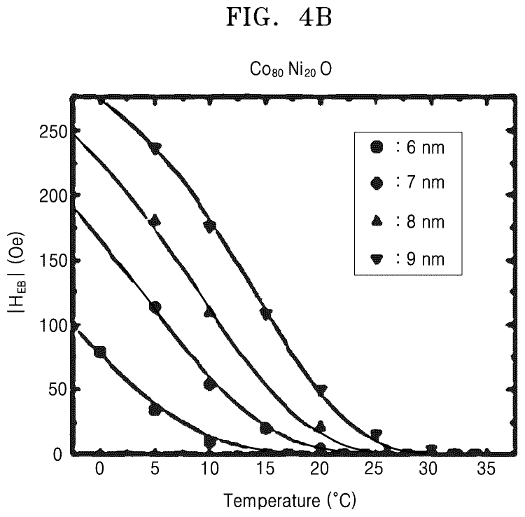

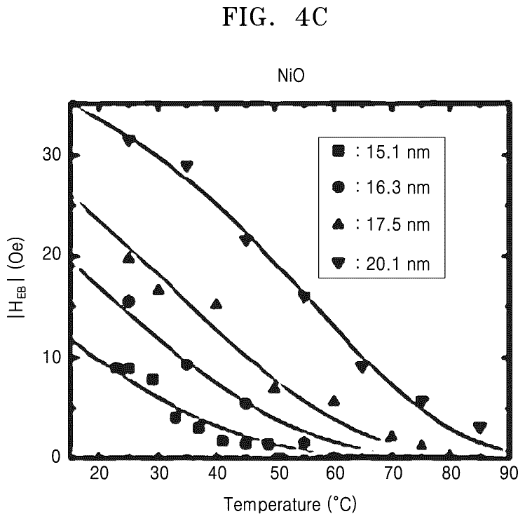

The strength of the exchange bias field may be controlled by the material composition ratio and/or a thickness of the antiferromagnetic material. For example, FIGS. 3A, 3B, and 3C show examples of the relation between the thickness of the antiferromagnetic material (t_{AFM}) and the strength of the exchange bias field (H_{EB}). The antiferromagnetic material is Co_{1-X}Ni_{X}O, and FIGS. 3A, 3B, and 3C show cases in which X=0.1, X=2, and X=1, respectively. The temperatures are 10° C., 20° C., and 25° C. in FIG. 3A, FIG. 3B, and FIG. 3C, respectively. Referring to FIGS. 3A, 3B, and 3C, it can be seen that the greater the thickness of the antiferromagnetic material (t_{AFM}), the greater the strength of the exchange bias field (H_{EB}). FIGS. 4A, 4B, and 4C show examples of the relation between the temperature and the intensity of the exchange bias field. The antiferromagnetic material is Co_{1-X}Ni_{X}O, and FIGS. 4A, 4B, and 4C show cases in which X=0.1, X=2, and X=1, respectively. Referring to FIGS. 4A, 4B, and 4C, it can be seen that the greater the temperature, the lesser the strength of the exchange bias field. Accordingly, it may be seen that the material composition ratio and/or the thickness of the antiferromagnetic material for obtaining a desired exchange bias field strength may be determined by considering the operating temperature of the racetrack wire 10. Alternatively or additionally, it may be seen that the strength of the exchange bias field may be controlled by temperature.

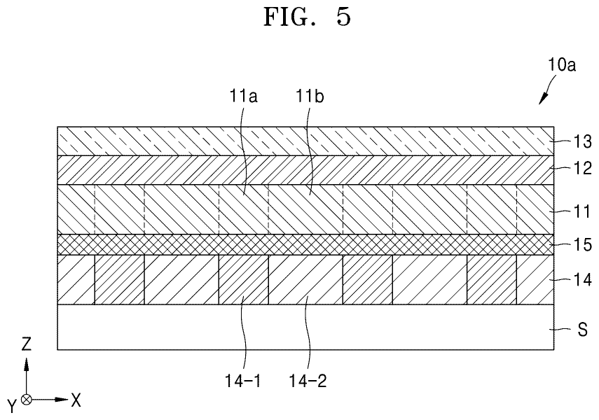

FIG. 5 is a schematic cross-sectional view of a racetrack wire according to some example embodiments. The racetrack wire 10a of the embodiment is different from the racetrack wire 10 of FIG. 1 in that the former further includes a spin orbit torque layer 15. The same reference numerals are used for the same components, redundant descriptions thereof are omitted, and differences are mainly described.

Referring to FIG. 5, the racetrack wire 10a may further include a spin orbit torque layer 15. The spin orbit torque layer 15 may be placed below the free layer 10. The spin orbit torque layer 15 may be disposed between the free layer 10 and the pinning site providing layer 14. The spin orbit torque layer 15 may induce spin orbit torque by the current flowing inside. Accordingly, magnetization reversal on the free layer 11 may be possible at a low operating current density during a write operation for writing the magnetic domain in the free layer 11. Alternatively or additionally, movement of the domain wall may be possible at low operating current density even during a movement operation of moving the magnetic domain along the free layer 11. As an example, the spin-orbit torque layer 15 may include a non-magnetic heavy metal having an atomic number of 30 or greater. For example, the spin orbit torque layer 50 may include, but is not limited to, at least one of Ir, Ru, Ta, Pt, Pd, Bi, Ti, and W or alloys thereof.

In some example embodiments, the spin orbit torque layer 15 may have a two-layer structure of an orbital hall conductance (OHC) material layer/conversion layer. In order to obtain an operating speed of 1 nanosecond in the magnetic memory device employing the spin orbit torque layer 15, it may be necessary or desirable to lower the operating current density. To this end, it may be necessary or desirable to increase the amount of spin current generated in the spin orbit torque layer 15. In the spin orbit torque layer 15, it may be necessary or desirable to increase the spin Hall angle (SHA), which is the efficiency of converting charge current into spin current by the spin Hall effect, and the spin Hall conductance (SHC), which is the amount of spin current that the spin orbit torque material itself can generate. When a current is applied to an OHC material layer having an OHC higher than the SHC exhibited by Pt, which is a general spin orbit torque material, an orbit current is generated. The orbit current may be converted into a spin current by the conversion layer. Since the spin current may be generated by the conversion layer itself, a great spin current may be generated by the spin orbit torque layer 15 having a two-layer structure including an OHC material layer and a conversion layer, and thus, magnetization reversal or domain wall movement with respect to the free layer 11 may be possible at a low operating current density. The OHC material layer may include elements having great OHC and/or an alloy thereof. For example, the OHC material layer may include at least one of Ir, IrMn, PtMn, V, Cr, Mn, Nb, Mo, Ru, Ta, W, and Re. The conversion layer may include at least one of Pt and rare earth elements such as Tb, Gd, Sm, and Dy.

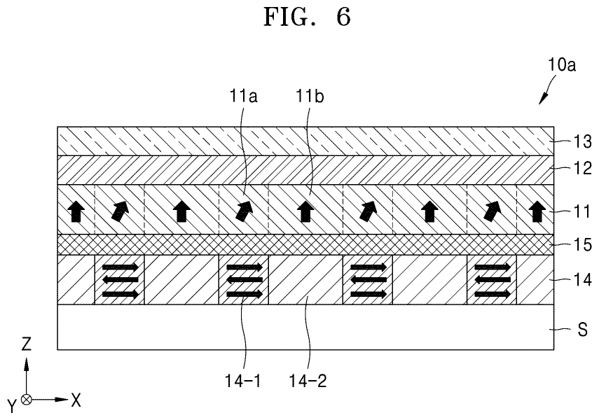

FIG. 6 is a drawing showing a function of the pinning site providing layer 14 in the racetrack wire 10a shown in FIG. 5. Referring to FIG. 6, in the racetrack wire 10a, the exchange bias field caused by the antiferromagnetic material acts as a stray magnetic field in the third region 11a of the free layer 11. Accordingly, the magnetic anisotropy energy of the third region 11a of the free layer 11 may become lower than the magnetic anisotropy energy of the fourth region 11b. This is indicated by a thick arrow tilted with respect to the +Z direction in the third area 11a and a thick arrow in the +Z direction in the fourth area 11b in FIG. 6. When the magnetic domain moves, for example, in the −X direction, the movement speed of the domain wall is affected by the magnetic anisotropy energy, and the lower the magnetic anisotropy energy, the lower the speed of the domain wall movement. Accordingly, the first region 14-1 of the pinning site providing layer 14 may form the pinning site in the third region 11a of the free layer 11 facing the first region 14-1, and the magnetic domain may be pinned to the third region 11a of the free layer 11.

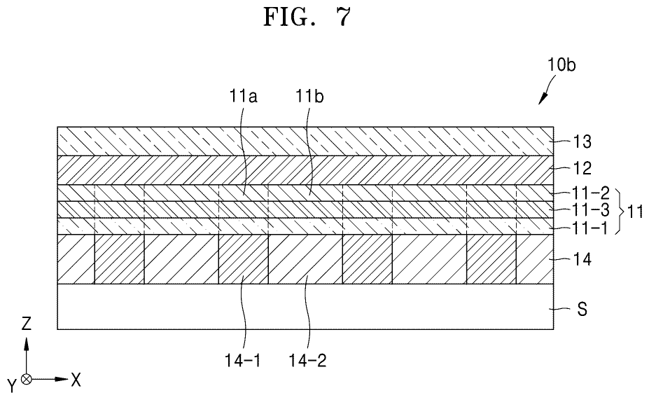

FIG. 7 is a schematic cross-sectional view of a racetrack wire 10b according to some example embodiments. The racetrack wire 10b of the embodiment is different from the racetrack wire 10 of FIG. 1 in that the free layer 11 of the former has a multi-layer structure. The same reference numerals are used for the same components, redundant descriptions thereof are omitted, and differences are mainly described.

Referring to FIG. 7, the free layer 11 may have a multi-layer such as a three-layer structure including a synthetic antiferromagnetic (SAF) coupling layer, that is, an SAF structure. For example, the free layer 11 may include a first free layer 11-1, a second free layer 11-2, and the SAF coupling layer 11-3 disposed therebetween. The first free layer 11-1 and the second free layer 11-2 may be ferromagnetic layers including a ferromagnetic material. The first free layer 11-1 and the second free layer 11-2 may be formed of or include the same ferromagnetic material, and/or may be formed of or include different ferromagnetic materials. The SAF coupling layer 11-3 may include a non-magnetic metal material such as Ru or Ir. The first free layer 11-1 and the second free layer 11-2 may form a synthetic antiferromagnet through the Ruderman-Kittel-Kasuya-Yosida (RKKY) interaction using the SAF coupling layer 11-3 as a medium. For example, a stable state may be achieved when the magnetization directions of the first free layer 11-1 and the second free layer 11-2 are opposite to each other (e.g., antiparallel). Accordingly, the free layer 11 may have a magnetic structure in which the magnetization directions of the first free layer 11-1 and the second free layer 11-2 are opposite to each other. The SAF coupling layer 11-3 may have an appropriate thickness range to mediate the RKKY interaction. For example, the thickness of the SAF coupling layer 11-3 may be about 0.5 nm or more and about 3 nm or less.

As described above, the structure of forming the pinning site by doping an impurity on the free layer 11 may be difficult to be applied to the free layer 11 having an SAF structure. According to some example embodiments, since the pinning site providing layer 14 is used, a plurality of pinning sites may be provided in the free layer 11 having an SAF structure.

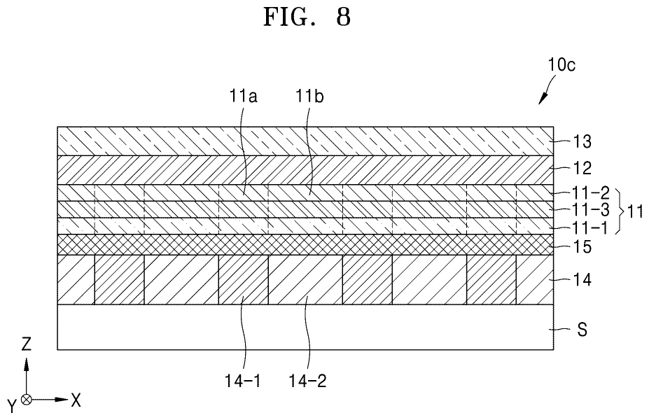

FIG. 8 is a schematic cross-sectional view of a racetrack wire 10c according to some example embodiments. The racetrack wire 10c of the embodiment is different from the racetrack wire 10b of FIG. 7 in that the former further includes the spin orbit torque layer 15. The description of the spin orbit torque layer 15 described with reference to FIG. 5 may be equally applied to the racetrack wire 10c illustrated in FIG. 8.

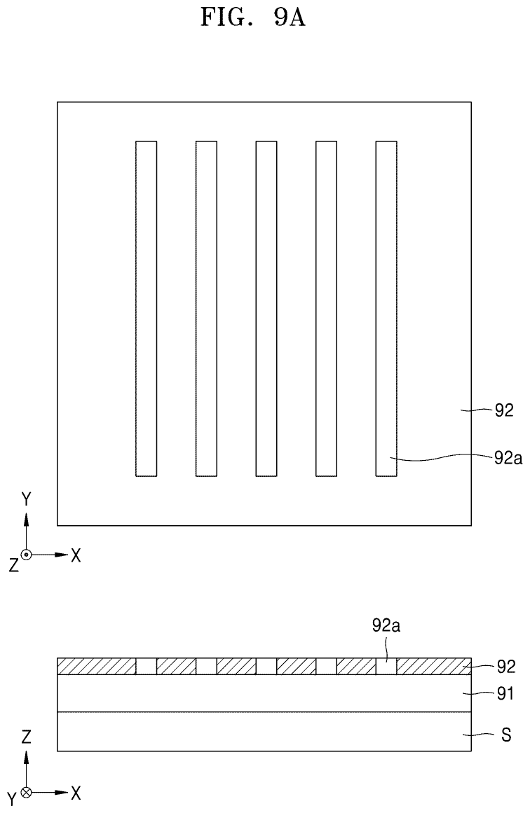

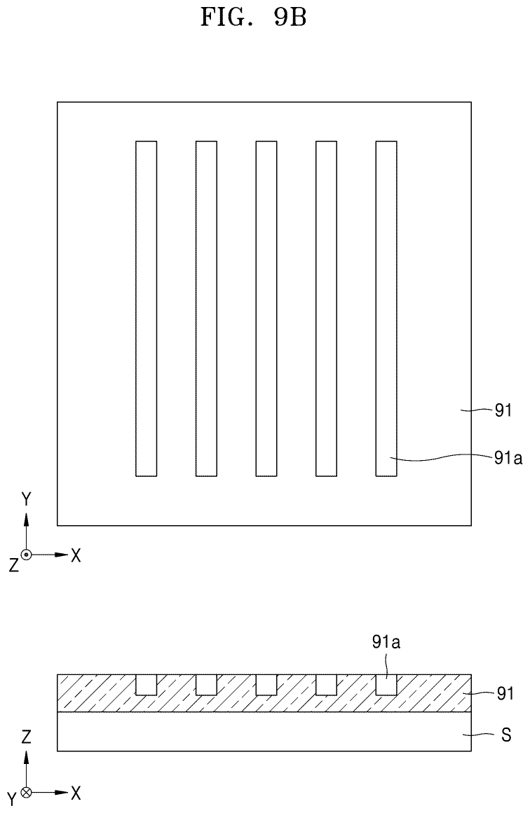

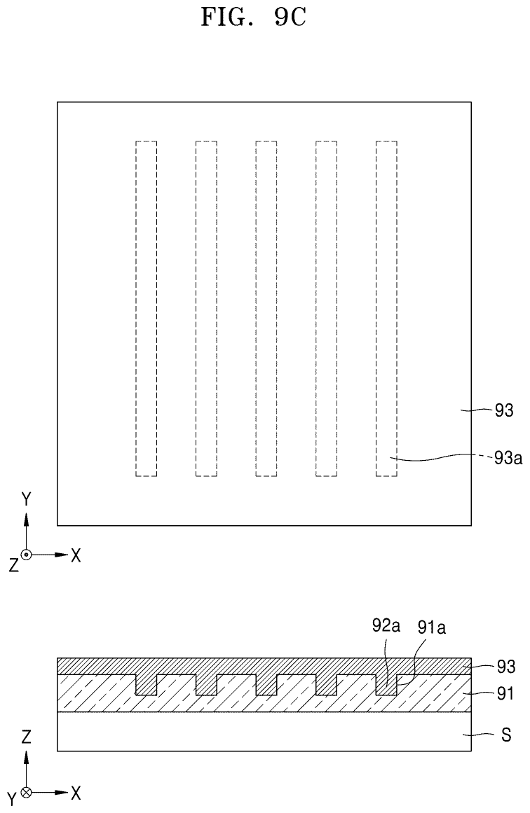

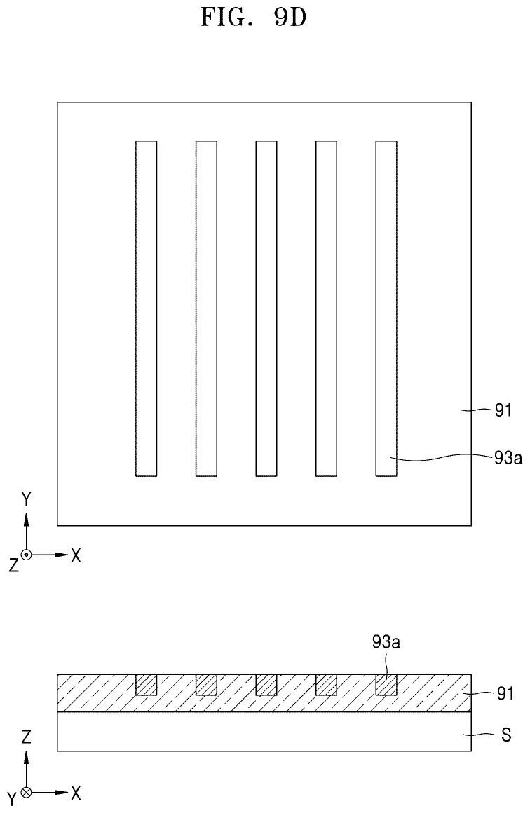

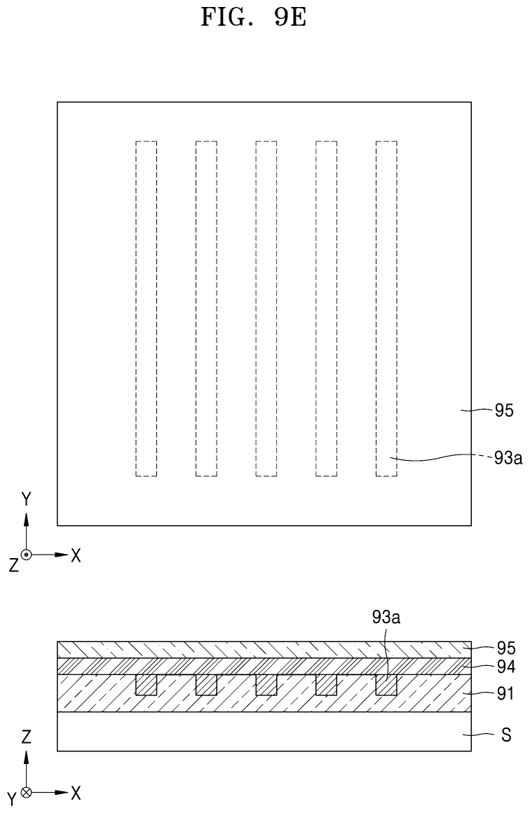

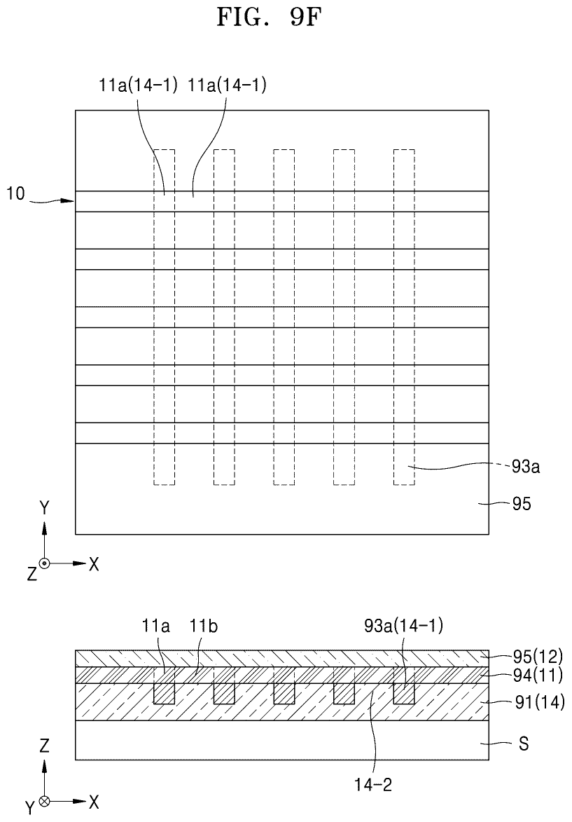

FIGS. 9A to 9F show an example of a method of manufacturing a racetrack wire. Referring to FIG. 9A, a first layer 91 including a non-antiferromagnetic material is formed on the substrate S. The non-antiferromagnetic material may include a paramagnetic material or a diamagnetic material. For example, the non-antiferromagnetic material may include at least one of SiO₂, AlOₓ, or nitride. A mask layer 92 is formed on the first layer 91. A plurality of openings 92a exposing the first layer 91 are formed by patterning the mask layer 92. Then, after etching the first layer 91 through the plurality of openings 92a, e.g., with an isotropic and/or an anisotropic etch, the mask layer 92 is removed. Then, as shown in FIG. 9B, a plurality of openings 91a are formed in the first layer 91.

As shown in FIG. 9C, a second layer 93 including an antiferromagnetic material is formed on the first layer 91. The antiferromagnetic material fills the plurality of openings 91a of the first layer 91. When the second layer 93 on the first layer 91 is removed, for example, by a chemical mechanical polishing (CMP) process and/or an etch-back process, a structure wherein the plurality of openings 91a of the first layer 91 are filled with an antiferromagnetic material 93a is formed, as shown in FIG. 9D.

Subsequently, as shown in FIG. 9E, a third layer 94 and a fourth layer 95 are sequentially deposited, e.g., sequentially laminated on the first layer 91. The third layer 94 may have a single-layer structure including a ferromagnetic material, or may have a multi-layer structure having an SAF material. The free layer 11 may be implemented by the third layer 94. The spin orbit torque layer 15 may be disposed between the third layer 94 and the first layer 91. The fourth layer 95 may include metal oxide, for example, magnesium oxide. For example, the fourth layer 95 may include MgO, MgAl₂O₄, or MgTiOₓ. The fourth layer 95 may have a single-layer structure or a multi-layer structure (e.g., a three-way structure). The aforementioned dielectric layer 12 may be implemented by the fourth layer 95. Although not shown in the drawing, a capping layer may be further provided as a protective layer on the fourth layer 95.

As shown in FIG. 9F, the third layer 94 and the fourth layer 95 are patterned into multiple regions in the Y direction. A portion of the first layer 91 filled with the antiferromagnetic material 93a is the first region 14-1, and a portion filled with a non-antiferromagnetic material between the plurality of first regions 14-1 is the second region 14-2. The third layer 94, for example, the free layer 11, includes a third region 11a facing the first region 14-1 and a fourth region 11b facing the second region 14-2. Thereby, the plurality of racetrack wires 10 arranged in the Y direction and extending in the X direction are formed.

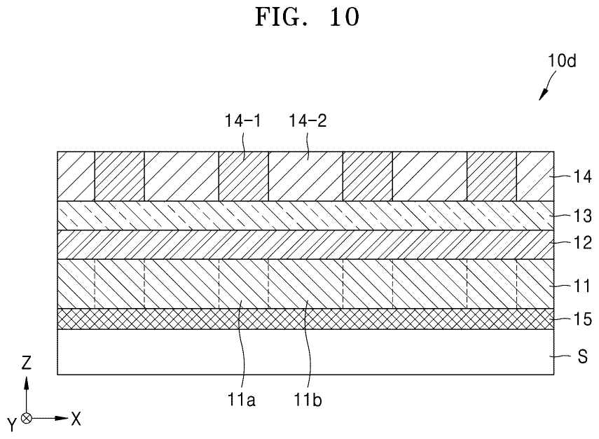

In some example embodiments, the pinning site providing layer 14 is arranged on the opposite side of the dielectric layer 12 with respect to the free layer 11, but the position of the pinning site providing layer 14 is not limited thereto. FIG. 10 is a schematic cross-sectional view of a racetrack wire 10d according to some example embodiments. The racetrack wire 10d of some example embodiment differs from some example embodiments of the racetrack wire described above in that the pinning site providing layer 14 of the racetrack wire 10d is arranged on top of the dielectric layer 12. Hereinafter, the same reference numerals are used for the same components, redundant descriptions thereof are omitted, and differences are mainly described.

Referring to FIG. 10, the free layer 11 may have a single-layer structure as shown in FIG. 1 or an SAF structure as shown in FIG. 7. The spin torque layer 15 may be disposed below the free layer 11. The dielectric layer 12 may be disposed on the free layer 11. The pinning site providing layer 14 is disposed on the dielectric layer 12. That is, pinning site providing layer 14 faces the free layer 11 with the dielectric layer 12 therebetween. The pinning site providing layer 14 includes the plurality of first regions 14-1 including an antiferromagnetic material and being apart from each other, and the plurality of second regions 14-2 disposed between the plurality of first regions 14-1.

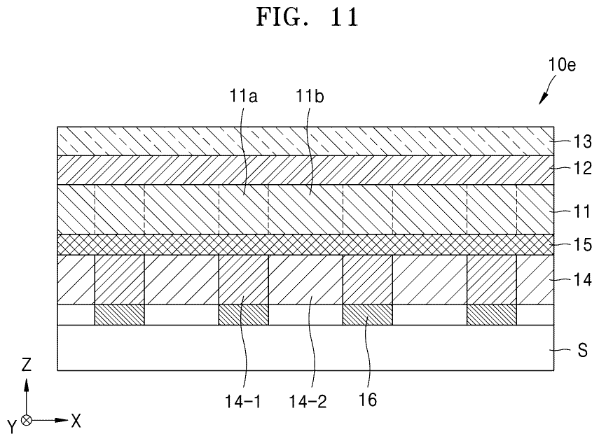

As mentioned above, the strength of the exchange bias field of an antiferromagnetic material may be controlled by temperature. Therefore, by controlling the temperature of the first region 14-1 of the pinning site providing layer 14, the antiferromagnetic material may provide an exchange bias field of appropriate strength. FIG. 11 is a schematic cross-sectional view of a racetrack wire 10e according to some example embodiments. The racetrack wire 10e of some example embodiments is different from some example embodiments of the racetrack wire described above in that former includes a temperature controller 16 to control the temperature of the first region 14-1 of the pinning site providing layer 14. Hereinafter, the same reference numerals are used for the same components, redundant descriptions thereof are omitted, and differences are mainly described.

Referring to FIG. 11, the free layer 11 may have a single-layer structure as shown in FIG. 1 or an SAF structure as shown in FIG. 7. The pinning site providing layer 14 is disposed below the free layer 11. The pinning site providing layer 14 includes the plurality of first regions 14-1 including an antiferromagnetic material and being apart from each other, and the plurality of second regions 14-2 disposed between the plurality of first regions 14-1. The spin torque layer 15 may be further arranged below the free layer 11 and between the free layer 11 and the pinning site providing layer 14. The plurality of temperature controllers 16 are disposed correspondingly to each of the plurality of first regions 14-1. The temperature controller 16 may be or include, for example, a temperature control electrode that generates Joule heat when a voltage is applied, or a heater that generates heat by receiving a current. The plurality of temperature controllers 16 may be driven individually and/or collectively.

Accordingly, the plurality of temperature controllers 16 may control the temperature of the plurality of first regions 14-1 such that the antiferromagnetic material may provide an exchange bias field of an appropriate strength to the third region 11a. Since the antiferromagnetic material loses antiferromagnetic characteristics at or above a blocking temperature thereof, that is, at or above the Neel temperature, and takes on characteristics of a paramagnetic material, the plurality of temperature controllers 16 may control the temperature of the first region 14-1 so as not to exceed the blocking temperature.

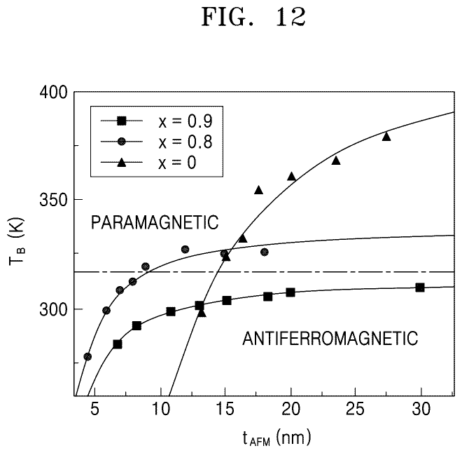

The blocking temperature depends on the material composition ratio and/or on thickness of the antiferromagnetic material. FIG. 12 is a graph showing an example of the relation between a thickness t_{AFM} and a blocking temperature T_{B} of the antiferromagnetic material. The antiferromagnetic material is Co_{1-X}Ni_{X}O. FIG. 12 shows the change in the relation between the thickness t_{AFM} and the blocking temperature T_{B} of the antiferromagnetic material when X=0.9, X=0.8, and X=0. Considering an operating temperature T_{OP} of the magnetic memory device, the material composition ratio and thickness t_{AFM} of the diamagnetic material may be determined such that the blocking temperature T_{B} is greater than the operating temperature T_{OP}.

When the temperature of the first region 14-1 exceeds the blocking temperature, the antiferromagnetic material takes on the characteristics of a paramagnetic material and does not provide an exchange bias field to the third region 11a. Accordingly, since the magnetic anisotropy energy of the third region 11a and the fourth region 11b of the free layer 11 become almost the same, the pinning site disappears. As a result, the temperature of the plurality of first regions 14-1 may be individually controlled such that the temperature of some of the plurality of first regions 14-1 reaches the blocking temperature or above. Thereby, some of the plurality of first regions 14-1 do not function as pinning sites. For example, the number and/or the location of the pinning sites may be flexibly adjusted without changing the physical structure of the racetrack wire.

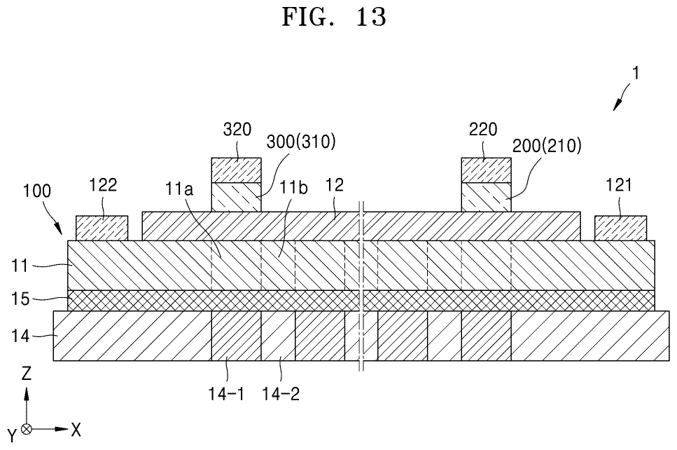

FIG. 13 is a schematic cross-sectional view of a magnetic memory device 1 according to some example embodiments. The magnetic memory device 1 of the present embodiment is a so-called racetrack memory device. Referring to FIG. 13, the magnetic memory device 1 may include a moving element (a racetrack) 100, a write element (a writer) (200), and a read element (a reader) (300).

The racetrack wire according to the embodiments of FIGS. 1, 5, 7, 8, 10, and 11 may be used as the moving element 100. Therefore, the description of the embodiments of the racetrack wire described above applies equally to the moving element 100. In FIG. 13, the racetrack wire 10a shown in FIG. 5 is applied as an example of the moving element 100. The moving element 100 may include the free layer 11, the dielectric layer 12, and the pinning site providing layer 14. The free layer 11 may have a single-layer structure including a ferromagnetic material, or may have a multi-layer structure having an SAF structure. The pinning site providing layer 14 may include the plurality of first regions 14-1 and the plurality of second regions 14-2. The first region 14-1 and the second region 14-2 are arranged alternately in the length direction (X). The free layer 11 includes a third region 11a and a fourth region 11b respectively facing the first region 14-1 and the second region 14-2 of the pinning site providing layer 14. Although not shown, the spin orbit torque layer 15 may be disposed between the free layer 11 and the pinning site providing layer 14. In FIG. 13, the substrate S is omitted.

The write element 200 generates a magnetic domain in the moving element 100, that is, the free layer 11. A pair of moving electrodes 121 and 122 are connected to the moving element 100 to supply a current to move the magnetic domain generated in the moving element 100, that is, the free layer 11, in the length direction (X). For example, the pair of moving electrodes 121 and 122 are connected to the free layer 11 at positions apart from each other in the length direction (X). The moving electrodes 121 and 122 may include, for example, TiN and/or Au. When a current, such as a DC current, is supplied to the moving element 100 through the pair of moving electrodes 121 and 122, the magnetic domain moves in the length direction (X) along the moving element 100, that is, the free layer 11. The read element 300 is apart from the write element 200 in the length direction (X) of the moving element 100 and reads the magnetic domain generated in a region, facing the write element 200, of the moving element 100, that is, the free layer 11.

The structure of the write element 200 is not particularly limited. The write element 200 according to some example embodiments may generate (inject) the magnetic domain into the free layer 11 through an inverse magnetostrictive effect. For example, the write element 200 may include a volume change material layer 210. The volume change material layer 210 may be disposed on the dielectric layer 12 and face the free layer 11. A write electrode 220 may be disposed on the volume change material layer 210. The write electrode 220 may include, for example, TiN and/or Au.

The volume change material layer 210 may include a ferroelectric material. The volume change material layer 210 may include, for example, one or more of HfO₂, Hf₁₋ₓZrₓO₂(1<x<0), Hf₁₋ₓAlₓO₂(1<x<0), BaTiO₃, or PbZr₁₋ₓTiₓO₃(1<x<0). The volume change material layer 210 may include a piezoelectric material. The volume change material layer 210 may include nitride or oxide. The volume change material layer 210 may include, for example, GaN, InN, AlN, BaTiO₃, PbZr₁₋ₓTiₓO₃(1<x<0), BiFeO₃, or ZnO. The volume change material layer 210 may maintain a polarization state at an applied voltage even after the applied voltage is removed.

When a voltage is applied to the volume change material layer 210 through the write electrode 220, a magnetic domain may be generated in the moving element 100, that is, the free layer 11, by the inverse magnetostrictive effect. In some example embodiments, when a first voltage is applied to the write electrode 220, the internal polarization direction of the volume change material layer 210 may be directed downward, and when a second voltage having an opposite polarity to the first voltage is applied to the write electrode 220, the internal polarization direction of the volume change material layer 210 may be directed upward. Therefore, the magnetization direction of the magnetic domain of the free layer 11 may be determined by the voltage applied to the write electrode 220. For example, the volume change material layer 210 may include a material showing piezoelectric characteristics. When voltage is applied to the volume change material layer 210, a volume change occurs therein. As the volume of the volume change material layer 210 changes, the volume of the dielectric layer 12 under the volume change material layer 210 changes, and accordingly, the volume of the free layer 11 under the dielectric layer 12 changes. A change in the volume of the free layer 11 causes a change in the lattice constant of the ferromagnetic material forming the free layer 11, thereby changing the magnetic moment of the ferromagnetic material. Therefore, a magnetic domain may be generated in the free layer 11 by applying a voltage to the volume change material layer 210. The magnetization direction of the magnetic domain generated in the free layer 11 may be determined by the voltage applied to the volume change material layer 210 through the write electrode 220.

The read element 300 may read the magnetic domain of the moving element 100, that is, the free layer 11, for example, by using a change in resistance of the magnetic tunneling junction MJT. The read element 300 may include a pinned layer 310 having a pinned magnetization direction. The magnetization direction of the pinned layer 310 does not change once it is determined. The pinned layer 310 may have a single-layer structure including a ferromagnetic material or may have a multi-layer structure having an SAF structure. The above description of the material and structure forming the free layer 11 may be equally applied to the pinned layer 310. The pinned layer 310 may be disposed on the dielectric layer 12 and face the free layer 11. The pinned layer 310, the dielectric layer 12, and the free layer 11 form a magnetic tunneling junction. A read electrode 320 may be disposed on the pinned layer 310. The read electrode 320 may include, for example, TiN and/or Au. If the magnetization directions of the pinned layer 310 and the free layer 11 are the same, the resistance of the magnetic tunneling junction decreases, and if the magnetization directions of the pinned layer 310 and the free layer 11 are opposite to each other, the resistance of the tunneling junction increases. By these characteristics, for example, the magnetic tunneling junction may be represented by data such as ‘0’ when having a low resistance value and may be represented by data such as ‘1’ when having a high resistance value.

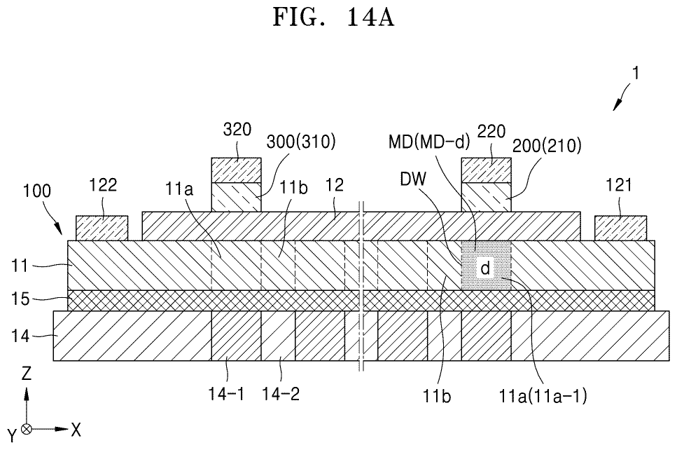

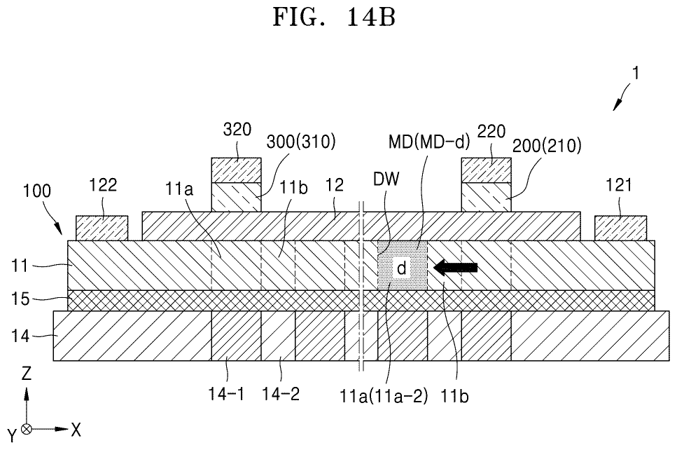

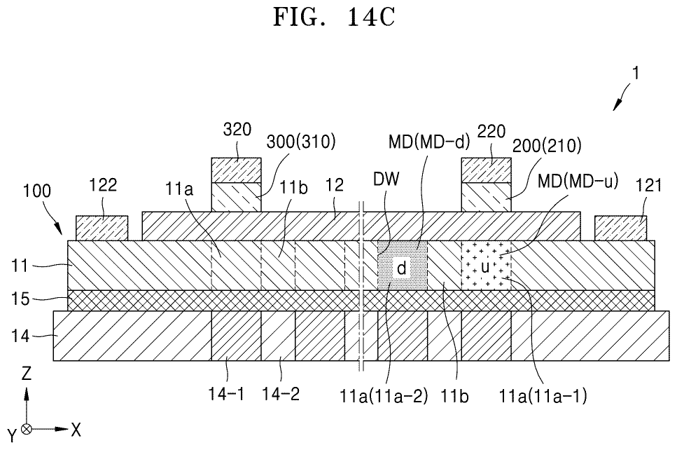

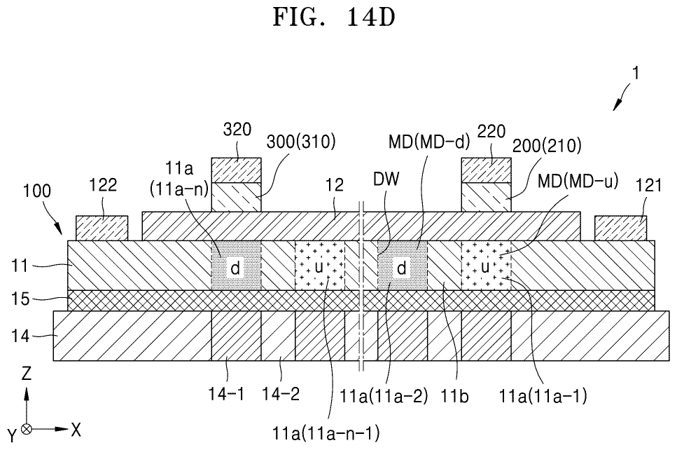

Hereinafter, a process of writing, moving, and reading a magnetic domain is described with reference to FIGS. 14A to 14D. Hereinafter, a magnetic domain of which the magnetization direction is in the +Z direction is referred to as an up domain and is indicated by “u” in the drawing, and a magnetic domain of which the magnetization direction is in the −Z direction is referred to as a down domain and is indicated by “d” in the drawing.

Referring to FIG. 14A, a writing voltage of, for example, −10 V may be applied to the volume change material layer 210 through the write electrode 220. Then, a magnetic domain MD with a magnetization direction in the −Z direction may be formed in a region facing the write element 200 of the free layer 11. In the drawings, the magnetic domain MD of which the magnetization direction is in the −Z direction is indicated as “MD-d”. By reducing the voltage applied to the write electrode 220 to, for example, −5 V, the magnetic domain MD may be determined. A domain wall DW forms a boundary between the magnetic domain MD and another region of the free layer 11. In a case where the spin orbit torque layer 15 is present, a spin current polarized in a specific direction is generated in the spin orbit torque layer 15 by a current applied through the write electrode 220, and a corresponding spin orbit torque is generated. The magnetization direction of the free layer 11 may be easily rotated by the spin orbit torque, and the magnetic domain MD of which the magnetization direction is in the −Z direction may be easily formed in the free layer 11. In some example embodiments, the write element 200 faces the first region 14-1 of the pinning site providing layer 14. Accordingly, a region facing the write element 200 of the free layer 11 is the third area 11a, and, in the drawing, the third area 11a facing the write element 200 of the free layer 11 is indicated by reference numeral “11a-1.” As previously described, the magnetic anisotropy energy of the third region 11a is lower than the magnetic anisotropy energy of the fourth region 11b due to the exchange bias field provided by the first region 14-1 of the pinning site providing layer 14. Accordingly, the magnetic domain MD may be stably formed in the third region 11a-1 facing the write element 200 of the free layer 11.

Subsequently, the magnetic domain MD may be moved toward the read element 300 as illustrated in FIG. 14B. A moving voltage may be applied to the moving element 100, that is, the free layer 11, through the pair of moving electrodes 121 and 122. The moving voltage may supply a current to the free layer 11 in a direction that moves the magnetic domain MD in the −X direction, for example. Accordingly, the magnetic domain MD moves from the third region 11a-1 along the free layer 11 in the −X direction. As described above, the movement speed of the magnetic domain MD, or in other words, the movement speed of the domain wall DW, is affected by the magnetic anisotropy energy of the free layer 11. The lower the magnetic anisotropy energy, the slower the movement of the domain wall DW. Therefore, when the domain wall DW is separated from the third region 11a-1 in the −X direction and then reaches the third region 11a-2, the movement speed of the domain wall DW slows down, and the magnetic domain MD-d reaches the third region 11a-2 and is pinned to the third region 11a-2. In addition, the material composition ratio and thickness of the antiferromagnetic material forming the first region 14-1 of the pinning site providing layer 14 are determined such that a stable exchange bias field at the operating temperature of the magnetic memory device 1 is provided, thereby stably maintaining the magnetic anisotropy energy of the third region 11a facing the first region 14-1 to be lower than that of the fourth region 11b. Therefore, unless a current is supplied to the free layer 11 through the moving electrode 121 and 122, the magnetic domain MD-d may be stably maintained in the third region 11a-2.

As illustrated in FIG. 14C, the volume change material layer 210 may generate a new magnetic domain in the free layer 11 based on the applied voltage. For example, by applying 10 V to the volume change material layer 210 through the write electrode 220, the magnetic domain MD having a magnetization direction in the +Z direction may be formed in the third region 11a-1 of the free layer 11. In the drawing, the magnetic domain MD of which the magnetization direction is in the +Z direction is indicated as “MD-u”. By reducing the voltage applied to the volume change material layer 210 through the write electrode 220 to, for example, 5 V, a magnetic domain MD-u of the third region may be determined.

By repeating the writing and moving of the magnetic domain MD, as shown in FIG. 14D, the plurality of magnetic domains MD may be respectively formed in the plurality of third regions 11a-1, 11a-2, . . . 11a-n-1, and 11a-n of the free layer 11.

The read element 300 may face one of the plurality of third regions 11a. For example, in some example embodiments, the read element 300 faces the third region 11a-n. The magnetic anisotropy energy of the third region 11a-n is lower than the magnetic anisotropy energy of the fourth region 11b adjacent to the third region 11a-n. Accordingly, the magnetic domain MD may be stably pinned to the third region 11a-n of the free layer 11 facing the read element 300. Therefore, the reading process described below may be performed stably.

In the states illustrated in FIG. 14D, a read voltage may be applied to the read element 300 through the read electrode 320. For example, the magnetization direction of the pinned layer 310 may be in the +Z direction. The magnetization direction of the magnetic domain MD of the third region 11a-n of the free layer (11) is in the −Z direction. Therefore, the magnetic tunneling junction formed by the pinned layer 310, the dielectric layer 12, and the free layer 11 has a high resistance value, and, for example, data “1” may be read. The plurality of magnetic domains MD may be sequentially moved in the −X direction along the moving element 100 to the third region 11a-n facing the read element 300, and data recorded in the magnetic domains MD may be read.

A current is applied to the racetrack wire 10, for example, the free layer 11, so as to move the magnetic domain. Joule heat is generated in the racetrack wire 10 by the applied current, thereby increasing the temperature of the magnetic memory device. Since all or some of the antiferromagnetic materials in the plurality of first regions 14-1 lose their characteristics as antiferromagnetic materials and turns to have a paramagnetic state, all or some of the plurality of pinning sites may be removed. Accordingly, the energy (current amount) required to move the magnetic domain along the racetrack wire 10 is reduced, thereby lowering the driving energy of the magnetic memory device.

In general, it may not be easy to maintain the position of the magnetic domain at room temperature without change for a long period of time. There are methods to provide pinning sites by forming notches in the racetrack wire or doping some regions of the racetrack wire with impurities to fix the position of the magnetic domain. However, in the method of forming a notch, since the width of the racetrack wire becomes narrower at a location where the notch is formed, the electrical resistance of the racetrack wire may become non-uniform in the length direction, and Joule heat may be generated near the notch, which may cause operational instability during the operation of the magnetic memory device. Alternatively or additionally, the method of using impurities may be difficult to be applied to the free layer of the SAF structure as described above.

According to some example embodiments, when the driving of the magnetic memory device is terminated, a current is not supplied to the racetrack wire 10, and thus, Joule heat is not generated. As the temperature of the magnetic memory device decreases, the antiferromagnetic materials of the plurality of first regions 14-1 recover their characteristics as antiferromagnetic materials, and the plurality of pinning sites are expressed. The positions of the plurality of magnetic domains are pinned with respect to the plurality of pinning sites. Accordingly, the position of the plurality of magnetic domains at room temperature is maintained stably without change such that the stability of data recorded in the magnetic memory device may be improved.

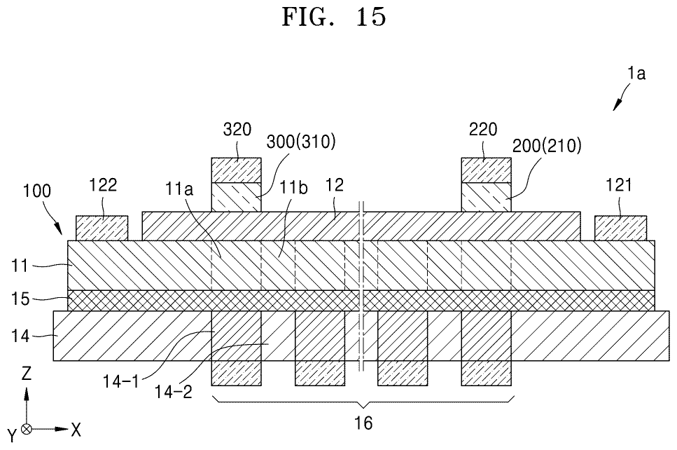

FIG. 15 is a schematic cross-sectional view of a magnetic memory device 1a according to some example embodiments. Referring to FIG. 15, the magnetic memory element 1a of the present embodiment differs from the magnetic memory element 1 of FIG. 13 in that the former has a plurality of temperature controllers 16. Hereinafter, the same reference numerals are used for the same components and differences are mainly described.

Referring to FIG. 15, the magnetic memory device 1a of some example embodiments includes the temperature controller 16. For example, the plurality of temperature controllers 16 may be disposed correspondingly to the plurality of first regions 14-1 of the pinning site providing layer 14. The temperature controller 16 may be, for example, a temperature control electrode to which a voltage is applied, or a heater that generates heat by receiving a current. The plurality of temperature controllers 16 may be driven individually or collectively. By providing the plurality of temperature controllers 16, the temperature of the plurality of first regions 14-1 may be controlled such that the antiferromagnetic material forming the first region 14-1 may provide an exchange bias field of an appropriate strength to the third region 11a of the free layer 11. Since the antiferromagnetic material loses antiferromagnetic material characteristics and takes on characteristics of a paramagnetic material when the temperature of the antiferromagnetic material reaches the blocking temperature or above, the plurality of temperature controllers 16 may control the temperature of the first region 14-1 so as not to exceed the blocking temperature. Accordingly, the plurality of pinning sites may be stably provided.

When the temperature of the first region 14-1 exceeds the blocking temperature, the antiferromagnetic material takes on the characteristics of a paramagnetic material and does not provide an exchange bias field to the third region 11a. Accordingly, since the magnetic anisotropy energy of the third region 11a and the fourth region 11b of the free layer 11 become almost the same, the pinning site disappears. When the magnetic memory device is driven at a low temperature, heat generated by the current supplied to the racetrack wire 10 to move the magnetic domain may be insufficient for the temperature of all or some of the plurality of first regions 14-1 to reach the blocking temperature or above. The temperature of the plurality of first regions 14-1 may be individually controlled by using the plurality of temperature controllers 16 such that the temperature of some or all of the plurality of first regions 14-1 reaches the blocking temperature or above. Then, some or all of the plurality of first regions 14-1 do not function as pinning sites. That is, the magnetic domain may be moved to a specific location on the racetrack wire by flexibly adjusting the number and location of the pinning sites without changing the physical structure of the racetrack wire.

For example, the plurality of temperature controllers 16 may be controlled to control a read position of the magnetic memory device. By controlling the plurality of temperature controllers 16 such that the temperature of the region facing the read element 300 of the magnetic memory device among the plurality of first regions 14-1 is less than the blocking temperature and the temperature of the remaining regions is equal to or greater than the blocking temperature, the magnetic domain may be stably pinned to the third region 11a-n (refer to FIG. 14D) of the free layer 11 facing the read element 300. Therefore, the reading process may be performed stably.

Alternatively or additionally, by controlling the plurality of temperature controllers 16, the plurality of magnetic domains may be grouped into one or more magnetic domains and moved as a magnetic domain group unit. For example, the plurality of temperature controllers 16 may be controlled such that the temperature of a region, among the plurality of first regions 14-1, corresponding to the magnetic domain at the forefront of the movement direction among the plurality of magnetic domains, is equal to or greater than the blocking temperature, and the temperatures of the remaining regions are less than the blocking temperature. Then, among the plurality of first regions 14-1, the region corresponding to the magnetic domain at the forefront of the movement direction among the plurality of magnetic domains is where the pinning site is eliminated (erased region), and the remaining regions act as pinning sites (pinning regions). In this state, when a current is applied to the racetrack wire to move the magnetic domain, only the forefront magnetic domain moves, and the magnetic domains corresponding to the remaining regions are pinned to the pinning region and do not move. Furthermore, by controlling a plurality of temperature controllers 16 so that two or more erased regions are formed, the plurality of magnetic domains may be moved as a magnetic domain group unit including two or more magnetic domains.

Some example embodiments of a method of driving the magnetic memory device 1a is described. The method of driving the magnetic memory device 1a according to some example embodiments may include providing the magnetic memory device 1a and controlling the temperature of the plurality of first regions 14-1 of the pinning site providing layer 14. The magnetic memory device 1a may have a structure as shown in FIG. 15. For example, the magnetic memory device 1a may include the moving element 100 including the free layer 11 and the pinning site providing layer 14 that provides the plurality of pinning sites to the moving element 100. The pinning site providing layer 14 includes a plurality of first regions 14-1 apart from each other in the length direction (X) of the moving element 100. Each of the plurality of first regions 14-1 includes an antiferromagnetic material. The antiferromagnetic material lowers the magnetic anisotropy energy of a region of the free layer 11 facing the first region 14-1. Accordingly, the pinning site may be provided in the third region 11a of the free layer 11. The magnetic memory device 1a includes a temperature controller 16 that controls the temperature of the plurality of first regions 14-1. The plurality of temperature controllers 16 respectively corresponding to the plurality of first regions 14-1 may be provided. Although not shown in the drawing, one temperature controller 16 may correspond to all of the plurality of first regions 14-1. Although not shown in the drawing, the plurality of temperature controllers 16 may correspond to some of the plurality of first regions 14-1.

In some example embodiments, controlling the temperature may include driving the temperature controller 16 to control the temperature of the plurality of first regions 14-1 to be less than the blocking temperature. The driving of the temperature controller 16 may be performed by supplying a current to the temperature controller 16. Accordingly, the plurality of first regions 14-1 may provide an appropriate exchange bias field or a stray field to the third region 11a of the free layer 11, thereby forming the plurality of pinning sites in the free layer 11.

In some example embodiments, controlling the temperature may include driving the temperature controller 16 to control the temperature of at least some of the plurality of first regions 14-1 to be the same as or above the blocking temperature. For example, during the movement operation of the magnetic memory device 1a, the plurality of temperature controllers 16 may be controlled such that the temperature of all of the plurality of first regions 14-1 is greater than the blocking temperature. Accordingly, the amount of current applied to the racetrack wire 10 during the movement operation may be reduced, thereby reducing the operating energy of the magnetic memory device 1a. In addition, when the operation of the magnetic memory device 1a is terminated, the temperature of the magnetic memory device 1a is reduced, and, as the plurality of first regions 14-1 recover antiferromagnetic characteristics, the magnetic domain may be pinned to the pinning sites provided by the plurality of first regions 14-1 and the performance of retaining information recorded in the magnetic memory device 1a at room temperature may be improved.

For example, by driving some of the plurality of temperature controllers 16, the temperature of corresponding areas among the plurality of first areas 14-1 may be controlled to be the same as or above the blocking temperature. Accordingly, the number and/or the position of the pinning sites may be adjusted by removing some of the plurality of pinning sites. For example, by controlling the plurality of temperature controllers 16 such that the region facing the read element 300 among the plurality of first regions 14-1 is a pinned region where the pinning site is valid, and the remaining regions are erased regions where the pinning sites are eliminated, the magnetic domain may be pinned to the region of the free layer 11 facing the read element 300, thereby improving the stability of the read operation. For example, by controlling the temperature controller 16 such that an appropriate number of regions among the plurality of first regions 14-1 are formed as erased regions, the plurality of magnetic domains may be moved as a magnetic domain group unit including one or more magnetic domains.

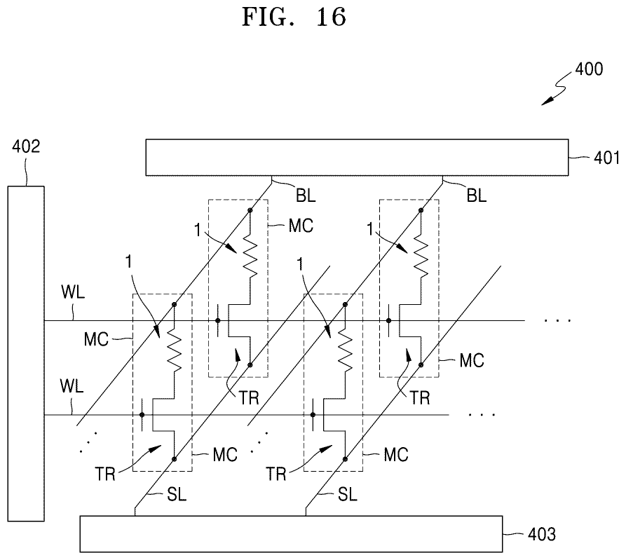

FIG. 16 is a circuit diagram schematically showing the structure of a memory apparatus 400 including a plurality of memory cells MC. Referring to FIG. 16, the memory apparatus 400 may include a plurality of bit lines BL, a plurality of word lines WL, a plurality of source lines SL, a plurality of memory cells MC respectively arranged at intersections of the plurality of bit lines BL and the plurality of word lines WL, a bit line driver 401 for applying a current to the plurality of bit lines BL, a word line driver 402 for applying a current to the plurality of word lines WL, and a source line driver 403 for applying a current to the plurality of source lines SL. Each memory cell MC may include a magnetic memory device 2 and one or more switching devices TR connected to electrodes of the magnetic memory device 2. The magnetic memory device 2 may have the structure shown in FIG. 13 or 15. The memory apparatus 400 illustrated in FIG. 16 may be, for example, a magnetic random-access memory (MRAM) and may be used in electronic devices that use nonvolatile memory.

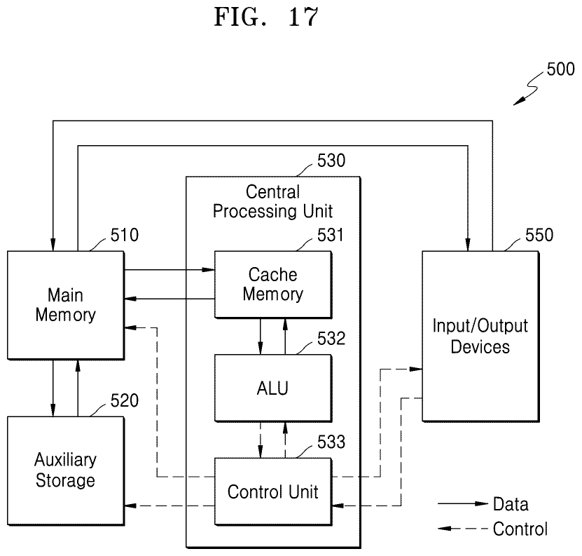

The memory apparatus 400 described above may be used to store data in various electronic apparatuses. FIG. 17 is a conceptual diagram schematically showing a device architecture that may be applied to an electronic apparatus according to embodiments. Referring to FIG. 17, the electronic apparatus 500 may include main memory 510, an auxiliary storage 520, a central processing unit (CPU) 530, and an input/output apparatus 540. The CPU 530 may include cache memory 531, an arithmetic logic unit (ALU) 532, and a controller 533. The cache memory 531 may include a static random-access memory (SRAM). The main memory 510 may include a dynamic random-access memory (DRAM) device and the secondary storage 520 may include the memory apparatus 400 according to some example embodiments. Alternatively, the cache memory 531, the main memory 510, and the auxiliary storage 520 may all include the memory apparatus 400 according to some example embodiments. In some cases, the electronic apparatus 500 may be implemented in a form wherein computing unit devices and memory unit devices are adjacent to each other in a single chip, without distinction of the above-described sub-units.

While the memory device and/or the method of operating the memory device have been described with reference to the embodiments thereof, the descriptions are only examples, and it will be understood by those of ordinary skill in the art that various changes in form and details may be made therein.

According to some example embodiments, the plurality of pinning sites are provided in the free layer by exchange bias fields or stray fields provided from regions of the pinning site providing layer including an antiferromagnetic material. Therefore, it may be possible to implement a magnetic memory device with improved positional stability of the magnetic domain without changing the structure and rheological properties of the free layer. In addition, the magnetic memory device with improved data retention performance may be implemented.

According to the embodiments, the temperature of regions of the pinning site providing layer including an antiferromagnetic material may be controlled using the temperature controller. Therefore, the number and positions of pinning sites in the magnetic memory device may be varied without changing the physical structure of the magnetic memory device.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that embodiments described herein should be considered in a descriptive sense only and not for purposes of limitation. Descriptions of features and/or aspects within each example embodiment should typically be considered as available for other similar features or aspects in other example embodiments. For example, example embodiments may include one or more feature described with reference to one or more figures, and may also include one or more other features described with reference to one or more other figures. While one or more embodiments have been described with reference to the figures, it will be understood by those of ordinary skill in the art that various changes in form and details may be made therein without departing from the spirit and scope as defined by the following claims.

What is claimed is:

1. A magnetic memory device comprising:
a moving element comprising a free layer;
a write element configured to generate a magnetic domain on the free layer;
a moving electrode configured to supply a current to move the magnetic domain to the moving element;
a read element apart from the write element in a length direction of the moving element and configured to read the magnetic domain of the free layer; and
a pinning site providing layer facing the free layer, wherein
the pinning site providing layer includes a plurality of first regions that comprise an antiferromagnetic material, are apart from each other in the length direction of the moving element, and are configured to reduce a magnetic anisotropy energy of regions of the free layer facing the plurality of first regions.

2. The magnetic memory device of claim 1, wherein the antiferromagnetic material comprises at least one of an oxide including one or more of Ni, Co, Mn, Fe, Cr, or Ru, IrMn, or PtMn.

3. The magnetic memory device of claim 1, wherein the antiferromagnetic material comprises at least one of 3d-electrons or 4f-electrons.

4. The magnetic memory device of claim 1, wherein
the pinning site providing layer comprises a plurality of second regions alternately arranged with the plurality of first regions, and
the plurality of second regions comprise at least one non-antiferromagnetic material.

5. The magnetic memory device of claim 4, wherein the non-antiferromagnetic material comprises at least one of the paramagnetic material and the diamagnetic material.

6. The magnetic memory device of claim 4, wherein the non-antiferromagnetic material comprises an antiferromagnetic material having a Neel temperature less than an operating temperature of the magnetic memory device.

7. The magnetic memory device of claim 1, further comprising:
a spin orbit torque layer facing the free layer and configured to provide a spin orbit torque to the free layer, wherein
the spin orbit torque layer is between the free layer and the pinning site providing layer.

8. The magnetic memory device of claim 1, further comprising:
a dielectric layer disposed on the free layer.

9. The magnetic memory device of claim 8, wherein the pinning site providing layer is on the dielectric layer.

10. The magnetic memory device of claim 1, wherein the free layer has one of a single-layer structure comprising an antiferromagnetic material, or
a synthetic antiferromagnetic (SAF) structure comprising a first free layer, a second free layer, and an SAF coupling layer disposed between the first free layer and the second free layer, wherein the first free layer and the second free layer each comprise a ferromagnetic material.

11. The magnetic memory device of claim 1, further comprising:
a temperature controller configured to control a temperature of the plurality of first regions.

12. The magnetic memory device of claim 11, wherein the temperature controller comprises a plurality of temperature controllers respectively corresponding to the plurality of first regions.

13. A racetrack wire comprising:
a free layer configured to generate a magnetic domain;
a pinning site providing layer comprising a plurality of first regions comprising an antiferromagnetic material, apart from each other in a length direction of the free layer, and configured to reduce a magnetic anisotropy energy of regions of the free layer facing the plurality of first regions; and
a dielectric layer on the free layer.

14. The racetrack wire of claim 13, wherein
the pinning site providing layer comprises a plurality of second regions alternately arranged with the plurality of first regions, and
the plurality of second regions comprise at least one of a paramagnetic material and a diamagnetic material.

15. The racetrack wire of claim 13, further comprising:
a spin orbit torque layer facing the free layer and configured to provide a spin orbit torque to the free layer.

16. The racetrack wire of claim 13, wherein the free layer has one of a single-layer structure comprising an antiferromagnetic material, or
a synthetic antiferromagnetic (SAF) structure comprising a first free layer, a second free layer, and an SAF coupling layer disposed between the first free layer and the second free layer, wherein the first free layer and the second free layer each comprise a ferromagnetic material.

17. The racetrack wire of claim 13, further comprising:
a temperature controller configured to control a temperature of the plurality of first regions.

18. The racetrack wire of claim 11, wherein the temperature controller comprises a plurality of temperature controllers respectively corresponding to the plurality of first regions.

19. An operation method of a magnetic memory device, the operation method comprising:
providing the magnetic memory device comprising a free layer, a pinning site providing layer, and a temperature controller, wherein the pinning site providing layer includes a plurality of first regions that comprise an antiferromagnetic material, are apart from each other in a length direction of the moving element, and are configured to reduce a magnetic anisotropy energy of regions of the free layer facing the plurality of first regions, and the temperature controller is configured to control a temperature of the plurality of first regions; and
driving the temperature controller to control the temperature of the plurality of first regions to be less than a blocking temperature of the antiferromagnetic material.

20. The operation method of claim 19, further comprising:
driving the temperature controller to control the temperature of at least some of the plurality of first regions to be same as or above the blocking temperature.
